(19) United States
(12) Patent Application Publication
(10) Pub. No.: US 2025/0374666 A1
(43) Pub. Date: Dec. 4, 2025

(54) FLEXIBLE ARRANGEMENT OF SEMICONDUCTOR DEVICES

(71) Applicant: International Business Machines Corporation, Armonk, NY (US)

(72) Inventors: David Wolpert, Poughkeepsie, NY (US); Reinaldo Vega, Yorktown Heights, NY (US); James P. Mazza, Albany, NY (US); Nicholas Anthony Lanzillo, Albany, NY (US); Takashi Ando, Yorktown Heights, NY (US)

(21) Appl. No.: 18/732,134

(22) Filed: Jun. 3, 2024

(51) Int. Cl. H01L 27/092; H01L 21/822; H01L 23/528; H01L 27/06; H01L 29/06; H01L 29/423; H01L 29/66; H01L 29/775; H01L 29/786

(52) U.S. Cl. CPC H10D 84/856; H01L 23/5283; H01L 23/5286; H10D 30/014; H10D 30/43; H10D 30/6735; H10D 30/6757; H10D 62/121; H10D 84/038; H10D 88/00; H10D 88/01

(57) ABSTRACT

A semiconductor device includes a set of transistor devices including respective discrete gate structures, a set of gate separation regions, where each discrete gate structure is disposed between a pair of the gate separation regions. The semiconductor device also includes a set of gate contacts, where each gate contact is connected to a corresponding one of the discrete gate structures.

### BACKGROUND

The present application relates to semiconductors, and more specifically, to techniques for forming semiconductor structures. Semiconductors and integrated circuit chips have become ubiquitous within many products, particularly as they continue to decrease in cost and size. There is a continued desire to reduce the size of structural features and/or to provide a greater amount of structural features for a given chip size. Miniaturization, in general, allows for increased performance at lower power levels and lower cost. Present technology is at or approaching atomic level scaling of certain micro-devices such as logic gates, field-effect transistors (FETs), and capacitors.

### SUMMARY

Embodiments of the invention provide techniques for forming a flexible arrangement of semiconductor devices. While not limited thereto, the disclosed techniques are well suited for reliability assessments.

In one embodiment, a semiconductor device includes a set of transistor devices including respective discrete gate structures, a set of gate separation regions, where each discrete gate structure is disposed between a pair of the gate separation regions, and a set of gate contacts, where each gate contact is connected to a corresponding one of the discrete gate structures.

In another embodiment, a semiconductor device includes a grid of transistor devices, wherein the grid transistor devices are laid out in a plurality of rows within the grid, at least one first gate separation region including a conductive material, where the first gate separation region is disposed between at least one pair of the transistor devices in the grid. The semiconductor device also includes a plurality of second gate separation regions including dielectric material, where the second gate separation regions separate each of the other pairs of the transistor devices in the grid.

In yet another embodiment, a method includes forming one or more gate structures and removing portions of the one or more gate structures based on a pattern of gate cuts, where the pattern of gate cuts separates each transistor device in a set of transistor devices. The method also includes depositing a dielectric or conductive material into the removed portions of the one or more gate structures, to form a plurality of discrete gate regions.

These and other features and advantages of embodiments described herein will become more apparent from the accompanying drawings and the following detailed description.

### BRIEF DESCRIPTION OF THE DRAWINGS

FIG. 1A depicts a top view of a semiconductor structure indicating a Y cross-section location on which the cross-sectional view of FIG. 1B is based.

FIG. 1B depicts a cross-sectional view of the semiconductor structure at an intermediate stage in a fabrication process corresponding to line Y in FIG. 1.

FIG. 2 depicts a top view of a semiconductor structure indicating a Y cross-section location on which the cross-sectional views of FIGS. 3-8 are based.

FIG. 3 depicts a cross-sectional view of the semiconductor structure at an intermediate stage in a fabrication process corresponding to line Y in FIG. 2 prior to a gate cut process, according to an illustrative embodiment.

FIG. 4 depicts a cross-sectional view of the semiconductor structure corresponding to line Y in FIG. 2 following a gate cut process, according to an illustrative embodiment.

FIG. 5 depicts a cross-sectional view of the semiconductor structure corresponding to line Y in FIG. 2 following formation of gate cut regions being filled with a non-conductive material, according to an illustrative embodiment.

FIG. 6 depicts a cross-sectional view of the semiconductor structure corresponding to line Y in FIG. 2 following replacement of a specified gate cut region with a conductive material, according to an illustrative embodiment.

FIG. 7 depicts a cross-sectional view of the semiconductor structure corresponding to line Y in FIG. 2 following formation of middle-of-line (MOL) contacts, frontside back-end-of-line (BEOL) interconnects, and carrier wafer bonding, according to an illustrative embodiment.

FIG. 8 depicts a cross-sectional view of the semiconductor structure corresponding to line Y in FIG. 2 following removal of substrate and an etch stop layer, and formation of a backside interlayer dielectric (ILD) layer and backside interconnects, according to an illustrative embodiment.

FIG. 9 depicts a top view of a semiconductor structure comprising multiple logic gates, according to an illustrative embodiment.

FIG. 10 depicts a top view of a semiconductor structure comprising a non-rectangular logic gate, according to an illustrative embodiment.

### DETAILED DESCRIPTION

Illustrative embodiments of the invention may be described herein in the context of illustrative methods for forming contact and placeholder configurations for backside power delivery, along with illustrative apparatus, systems and devices formed using such methods. However, it is to be understood that embodiments of the invention are not limited to the illustrative methods, apparatus, systems, and devices but instead are more broadly applicable to other suitable methods, apparatus, systems, and devices.

It is to be understood that the various features shown in the accompanying drawings are schematic illustrations that are not necessarily drawn to scale. Moreover, the same or similar reference numbers are used throughout the drawings to denote the same or similar features, elements, or structures, and thus, a detailed explanation of the same or similar features, elements, or structures will not be repeated for each of the drawings. Further, the terms “exemplary” and “illustrative” as used herein mean “serving as an example, instance, or illustration.” Any embodiment or design described herein as “exemplary” or “illustrative” is not to be construed as preferred or advantageous over other embodiments or designs.

A FET is a transistor having a source, a gate, and a drain, and having action that depends on the flow of carriers (electrons or holes) along a channel that runs between the source and drain. Current through the channel between the source and drain may be controlled by a transverse electric field under the gate.

FETs are widely used for switching, amplification, filtering, and other tasks. FETs include metal-oxide-semiconductor (MOS) FETs (MOSFETs). Complementary MOS (CMOS) devices are widely used, where both n-type and p-type transistors (nFET and pFET) are used to fabricate logic and other circuitry. Source and drain regions of a FET are typically formed by adding dopants to target regions of a semiconductor body on either side of a channel, with the gate being formed above the channel. The gate includes a gate dielectric over the channel and a gate conductor over the gate dielectric. The gate dielectric is an insulator material that prevents large leakage current from flowing into the channel when voltage is applied to the gate conductor while allowing applied gate voltage to produce a transverse electric field in the channel.

Various techniques may be used to reduce the size of FETs. One technique is through the use of fin-shaped channels in fin field-effect transistors (FinFET). Before the advent of FinFET arrangements, CMOS devices were typically substantially planar along the surface of the semiconductor substrate, with the exception of the FET gate disposed over the top of the channel. FinFETs utilize a vertical channel structure, increasing the surface area of the channel exposed to the gate. Thus, in FinFET structures the gate can more effectively control the channel, as the gate extends over more than one side or surface of the channel. In some FinFET arrangements, the gate encloses three surfaces of the three-dimensional channel, rather than being disposed over just the top surface of a traditional planar channel.

Another technique useful for reducing the size of FETs is through the use of stacked nanosheet channels formed over a semiconductor substrate. Stacked nanosheets may be two-dimensional nanostructures, such as sheets having a thickness range on the order of 1 to 20 nanometers (nm). Nanosheets and nanowires are viable options for scaling to 7 nm and beyond. A general process flow for forming a nanosheet stack involves selectively removing sacrificial layers, which may be formed of silicon germanium (SiGe), between sheets of channel material, which may be formed of silicon (Si).

For continued scaling (e.g., to 2.5 nm and beyond), next-generation stacked FET devices may be used. Next-generation stacked FET devices provide a complex gate-all-around (GAA) structure. Conventional GAA FETs, such as nanosheet FETs, may stack multiple p-type nanowires or nanosheets on top of each other in one device, and may stack multiple n-type nanowires or nanosheets on top of each other in another device. Next-generation stacked FET structures provide improved track height scaling, leading to structural gains (e.g., such as 30-40% structural gains for different types of devices, such as logic devices, static random-access memory (SRAM) devices, etc.). In next-generation stacked FET structures, n-type and p-type nanowires or nanosheets are stacked on each other, eliminating n-to-p separation bottlenecks and reducing the device area footprint. There is, however, a continued desire for further scaling and reducing the size of FETs.

As discussed above, various techniques may be used to reduce the size of FETs, including using fin-shaped channels in FinFET devices, using stacked nanosheet channels formed over a semiconductor substrate, and using next-generation stacked FET devices.

Although embodiments described herein are discussed in connection with nanosheet stacks, the embodiments are not necessarily limited thereto, and may similarly apply to nanowire stacks.

The concept of buried power rail (BPR) refers to power rails that are buried below the back end of line (BEOL) metal stack, usually in-level with the transistor fins themselves. Back side power distribution networks (BSPDN), or grids, enable scaling beyond 5 nm with the back side being below the transistor substrate. The BPR technology enables the freeing up of resources for the dense logic connections often limiting modern processor performance. Further scaling of a standard logic cell is enabled by removing the overhead in the area occupied by the power rails. Finally, thicker low-resistance power rails are allowed, which enable lower voltage (IR) drops.

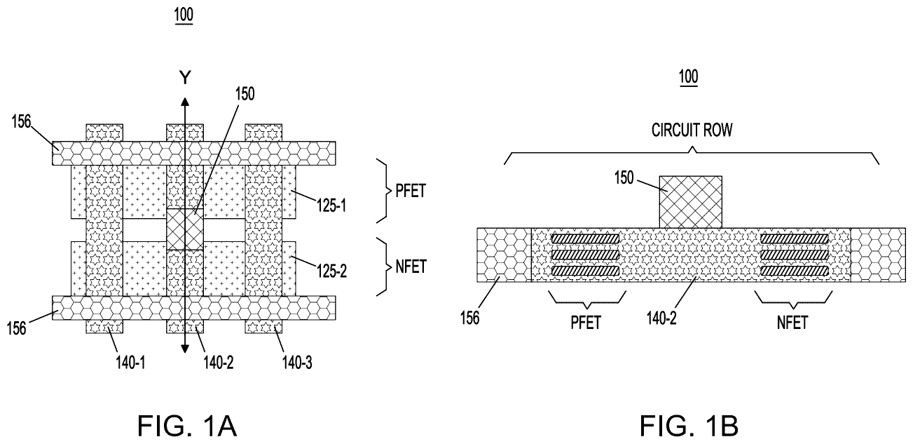

Conventional designs frequently rely on traditional circuit topologies with restrictive grid structures and fixed cell layouts, resulting in inefficient device utilization as described in more detail in conjunction with FIGS. 1A and 1B, for example.

Referring to FIG. 1A and to the cross-sectional view in FIG. 1B, which corresponds to the line Y in FIG. 1, a semiconductor structure 100 is shown having active areas 125-1 and 125-2 (collectively referred to as active areas 125) and gate structures 140-1, 140-2, and 140-3 (collectively referred to as gate structures 140). The active areas 125 generally correspond to source/drain regions of respective transistors. In this example, the active area 125-1 is assumed to correspond to source/drain regions associated with an pFET, and the active area 125-2 is assumed to correspond to source/drain regions associated with a nFET.

The semiconductor structure 100 also includes a gate contact 150 associated with gate structure 140-2 and gate cut regions 156. The gate cut regions 156 (also referred to as gate separation regions) can be formed as a result of a gate cut process. The gate cut process can be performed to remove portions of the gate structures 140, which is explained in more detail elsewhere herein. The gate cuts are performed on circuit row boundaries, resulting in a fixed circuit row where the gate structure 140-2 is shared by the pFET and the nFET, as shown in FIG. 1B.

In at least some embodiments, semiconductor devices are provided that offer increased flexibility and density compared to conventional techniques. More specifically, in at least some embodiments, regular gate cuts are formed between transistor devices, which advantageously allows for the creation of a set of discrete (e.g., individually addressable) gates that can be combined or kept separate as needed. In an example embodiment, the gate cut structures are formed in a consistent pattern to separate each row of nFET or pFET devices from any adjacent rows of nFET and pFET devices, such that a special process (e.g., a self-aligned patterning process) can be used instead of a conventional mask process. Such embodiments can further improve the uniformity of the gate cut structures and also improve patterning constraints (e.g., minimum cut width and/or spacing between gate cut and diffusion contact). Some of these embodiments enable non-rectangular reservations of transistor devices (e.g., pFETs and/or nFETs), nanowire/substrate spanning device stacks, uneven combinations of pFETs and nFETs (e.g., for beta optimization), complex pFET/nFET distributions, and local adjustment of gate lengths and/or widths and cell heights within a given circuit row, thereby enabling more complex and efficient gate topologies and increased device utilization density relative to conventional techniques.

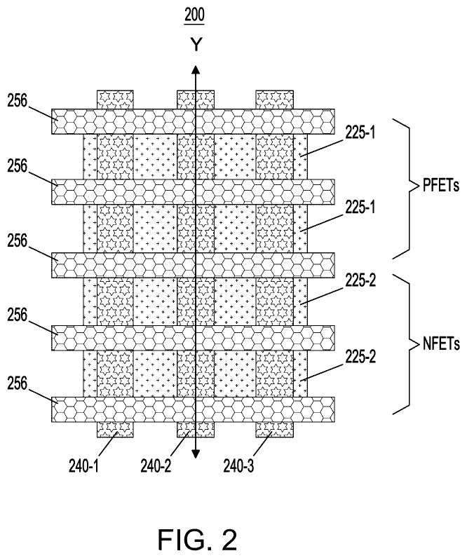

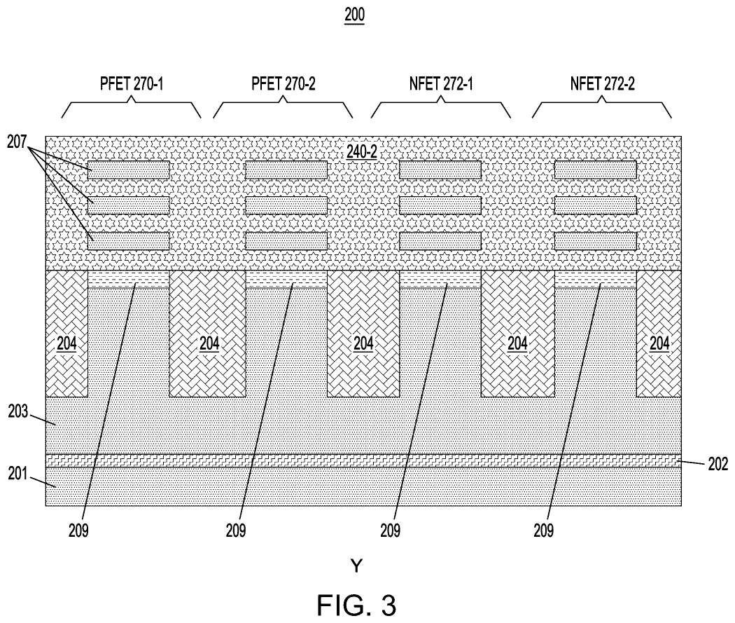

Referring to FIG. 2 and to the cross-sectional view in FIG. 3, which corresponds to the line Y in FIG. 2, a semiconductor structure 200 includes gate structures 240 and active areas 225-1 and 225-2 (collectively referred to as active areas 225), which, in some embodiments, correspond to source/drain regions of respective transistors (e.g., pFETs 270-1, 270-2 and nFETs 272-1, 272-2, as shown in FIG. 3). The semiconductor structure 200 also includes a stacked structure of channel layers 207. In an illustrative embodiment, the channel layers 207 comprise silicon. In an illustrative embodiment, the gate structures 240 are formed after a replacement metal gate (RMG) process in which sacrificial layers are removed and replaced with the gate structures 240.

In illustrative embodiments, each gate structure 240 includes a gate dielectric layer such as, for example, a high-K dielectric layer including, but not necessarily limited to, HfO₂ (hafnium oxide), ZrO₂ (zirconium dioxide), hafnium zirconium oxide, Al₂O₃ (aluminum oxide), and Ta₂O₅ (tantalum oxide). Examples of high-k materials also include, but are not limited to, metal oxides such as hafnium silicon oxynitride, lanthanum oxide, lanthanum aluminum oxide, zirconium oxide, zirconium silicon oxide, zirconium silicon oxynitride, tantalum oxide, titanium oxide, barium strontium titanium oxide, barium titanium oxide, strontium titanium oxide, yttrium oxide, aluminum oxide, lead scandium tantalum oxide, and lead zinc niobate.

According to an embodiment, each of the gate structures 240 include a metal gate portion including a work-function metal (WFM) layer, including but not necessarily limited to, for a pFET, titanium nitride (TiN), tantalum nitride (TaN) or ruthenium (Ru), and for an nFET, TiN, titanium aluminum nitride (TiAlN), titanium aluminum carbon nitride (TiAlCN), titanium aluminum carbide (TiAlC), tantalum aluminum carbide (TaAlC), tantalum aluminum carbon nitride (TaAlCN) or lanthanum (La) doped TiN, TaN, which can be deposited on the gate dielectric layer. The metal gate portions can also each further include a gate metal layer including, but not necessarily limited to, metals, such as, for example, tungsten, cobalt, zirconium, tantalum, titanium, aluminum, ruthenium, copper, metal carbides, metal nitrides, transition metal aluminides, tantalum carbide, titanium carbide, tantalum magnesium carbide, or combinations thereof deposited on the WFM layer and the gate dielectric layer. It should be appreciated that various other materials may be used for the metal gate portions as desired.

The lowermost gate structures 240 of the nanosheet stacks are formed on bottom dielectric isolation (BDI) layers 209, which can comprise, for example, silicon oxide SiOₓ, silicon oxycarbide (SiOC), SIN, SION, SiCN, BN, SiBCN, SiOCN or some other dielectric. The BDI layers 209 are situated beneath the bottom surfaces of the lowermost gate structures 240.

The first and second semiconductor substrates 201 and 203 comprise semiconductor material, including but not limited to, silicon (Si), III-V, II-V compound semiconductor materials, or other similar semiconductor materials. In addition, multiple layers of the semiconductor materials can be utilized as the semiconductor material for the first and second semiconductor substrates 201 and 203. An etch stop layer 202 is formed on the first semiconductor substrate 201, which can comprise, for example, SiOₓ or silicon germanium (SiGe). In illustrative embodiments, the etch stop layer 202 comprises a germanium concentration of about 25% (e.g., SiGe25), but the embodiments are not necessarily limited to SiGe25 for the etch stop layer 202. The second semiconductor substrate 203 comprising, for example, the same semiconductor material as the first semiconductor substrate 201, or other like semiconductor material, is formed on the etch stop layer 202.

Isolation regions 204 (e.g., shallow trench isolation (STI) regions) are formed in the second semiconductor substrate 203 between nanosheet stacks comprising channel layers 207 and gate structures 240. The isolation regions 204 can comprise a dielectric material that fills in the recessed portions of the second semiconductor substrate 203. The dielectric material may comprise, for example, silicon oxide (SiO2), silicon nitride (SIN), silicon oxynitride (SiON), silicon-carbon-nitride (SiCN), boron nitride (BN), silicon boron nitride (SiBN), silicoboron carbonitride (SiBCN), silicon oxycarbonitride (SiOCN) and combinations thereof, and is deposited using deposition techniques such as, for example, chemical vapor deposition (CVD), plasma enhanced CVD (PECVD), radio-frequency CVD (RFCVD), physical vapor deposition (PVD), atomic layer deposition (ALD), molecular beam deposition (MBD), pulsed laser deposition (PLD), and/or liquid source misted chemical deposition (LSMCD).

In some embodiments, source/drain regions corresponding to the active areas 225 are epitaxially grown between the nanosheet stacks. For example, the source/drain regions can comprise epitaxial layers grown from sides of channel layers 207. The terms “epitaxial growth and/or deposition” and “epitaxially formed and/or grown,” mean the growth of a semiconductor material (crystalline material) on a deposition surface of another semiconductor material (crystalline material), in which the semiconductor material being grown (crystalline over layer) has substantially the same crystalline characteristics as the semiconductor material of the deposition surface (seed material). In an epitaxial deposition process, the chemical reactants provided by the source gases are controlled, and the system parameters are set so that the depositing atoms arrive at the deposition surface of the semiconductor substrate with sufficient energy to move about on the surface such that the depositing atoms orient themselves to the crystal arrangement of the atoms of the deposition surface. Therefore, an epitaxially grown semiconductor material has substantially the same crystalline characteristics as the deposition surface on which the epitaxially grown material is formed.

The epitaxial deposition process may employ the deposition chamber of a chemical vapor deposition type apparatus, such as a metal-organic chemical vapor deposition (MOCVD), a rapid thermal chemical vapor deposition (RTCVD), a ultra-high vacuum chemical vapor deposition (UHVCVD), or a low-pressure chemical vapor deposition (LPCVD) apparatus. A number of different sources may be used for the epitaxial deposition of an in-situ doped semiconductor material. In some embodiments, the gas source for the deposition of an epitaxially formed semiconductor material may include silicon (Si) deposited from silane, disilane, trisilane, tetrasilane, hexachlorodisilane, tetrachlorosilane, dichlorosilane, trichlorosilane, and combinations thereof. In other examples, when the semiconductor material includes germanium, a germanium gas source may be selected from the group consisting of germane, digermane, halogermane, dichlorogermane, trichlorogermane, tetrachlorogermane, and combinations thereof. The temperature for epitaxial deposition typically ranges from 450° C. to 900° C. Although higher temperatures typically result in faster deposition, the faster deposition may result in crystal defects and film cracking.

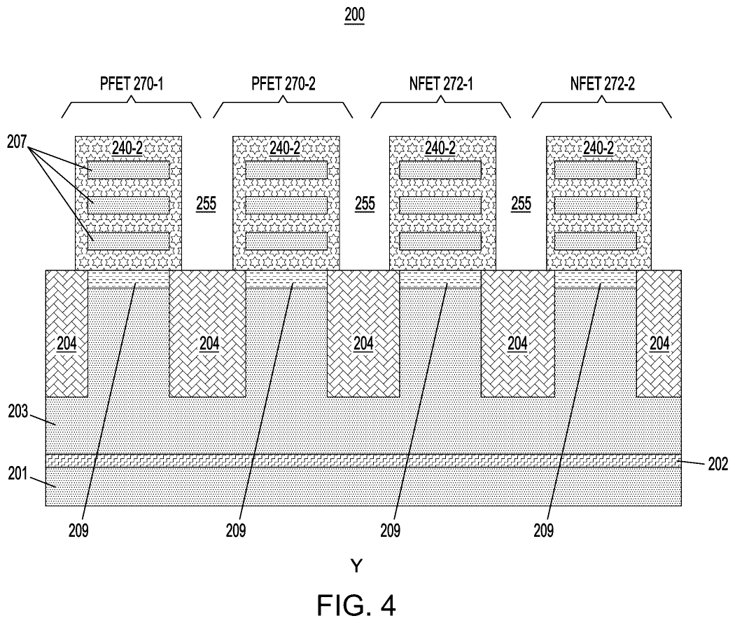

FIG. 4 depicts a cross-sectional view of the semiconductor structure corresponding to line Y in FIG. 2 following a gate cut process, according to an illustrative embodiment. Following formation of the gate structures 240, portions of the gate structures 240 between the nanosheet stacks comprising the channel layers 207 are removed using a gate cut process to create openings 255. For example, the portions removed by the gate cut process can extend down to respective surfaces of the isolation regions 204, as shown in FIG. 4. The gate cut process can include etching the gate structures 240 using, for example, RIE.

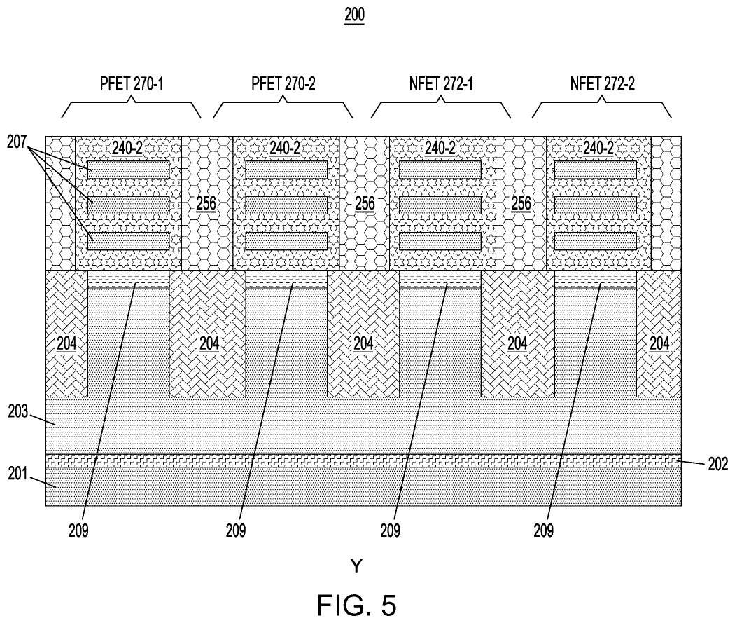

FIG. 5 depicts a cross-sectional view of the semiconductor structure corresponding to line Y in FIG. 2 following formation of gate cut regions 256, according to an illustrative embodiment. The openings 255 resulting from the gate cut process are filled with a dielectric material to form gate cut regions 256. The dielectric material can be deposited using deposition techniques such as, for example, CVD, PECVD, RFCVD, PVD, ALD, MBD, PLD, and/or LSMCD, followed by a planarization process, such as, CMP to remove excess portions of the dielectric material deposited on top of the gate structures 240. The dielectric material of the gate cut regions 256 may comprise, but is not necessarily limited to, SiN, SiC, SiON, SiOC, SiCN, BN, SiBN, SiBCN, SiOCN, SiOₓ or some other dielectric. In some embodiments, the semiconductor structure 200 shown in FIG. 5 represents an intermediate structure that provides increased flexibility for a place and route process of an electronic design automation (EDA) tool by enabling new (e.g., complex and/or non-rectangular) transistor device reservations, as discussed in more detail elsewhere herein.

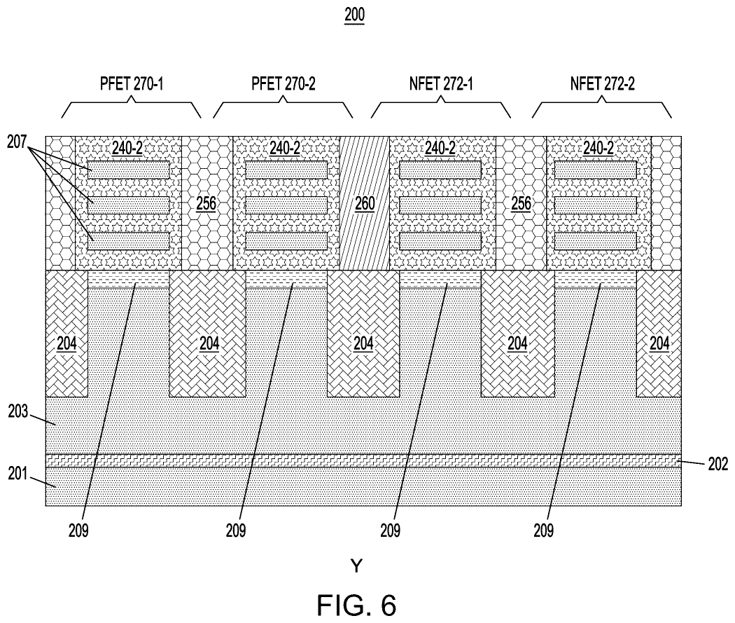

FIG. 6 depicts a cross-sectional view of the semiconductor structure 200 corresponding to line Y in FIG. 2 following replacement of a gate cut region 256 with a conductive material 260, according to an illustrative embodiment. FIG. 6 depicts removal of a single gate cut region 256. It is to be appreciated, however, that multiple gate cut regions 256 can be removed and replaced with the conductive material 260 in other embodiments. The process to remove the gate cut region 256 can include forming a mask over at least the portions of the gate cut regions 256. The gate cut region 256 can then be removed by selectively etching the gate cut region 256 with respect to the gate structures 240 and the isolation regions 204 using, for example, RIE. The conductive material 260 can include, for example, copper, aluminum, and/or other types of conductive material.

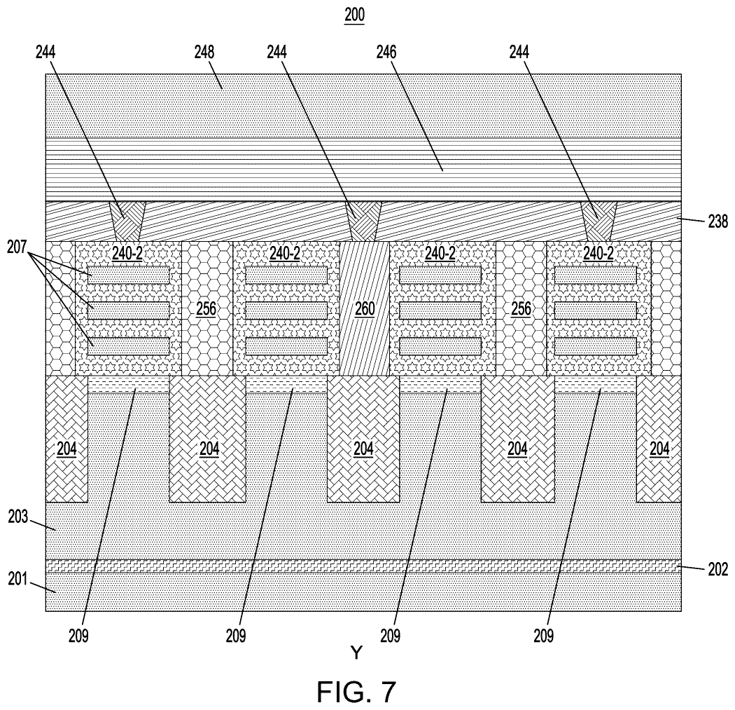

FIG. 7 depicts a cross-sectional view of the semiconductor structure corresponding to line Y in FIG. 2 following formation of middle-of-line (MOL) contacts, frontside back-end-of-line (BEOL) interconnects, and carrier wafer bonding, according to an illustrative embodiment.

The formation of the MOL contacts, the frontside BEOL interconnects, and the carrier wafer bonding can include the formation of an ILD layer 238, frontside gate contacts 244, frontside BEOL interconnects 246, and bonding of the structure (e.g., the frontside BEOL interconnects 246) to a carrier wafer 248.

The ILD layer 238 may be deposited using deposition techniques such as, for example, CVD, PECVD, RFCVD, PVD, ALD, MBD, PLD, and/or LSMCD, followed by a planarization process, such as, chemical mechanical planarization (CMP) to remove excess portions of the ILD layer 238. The ILD layer 238 may comprise, for example, SiOₓ, SiOC, SiOCN or some other dielectric.

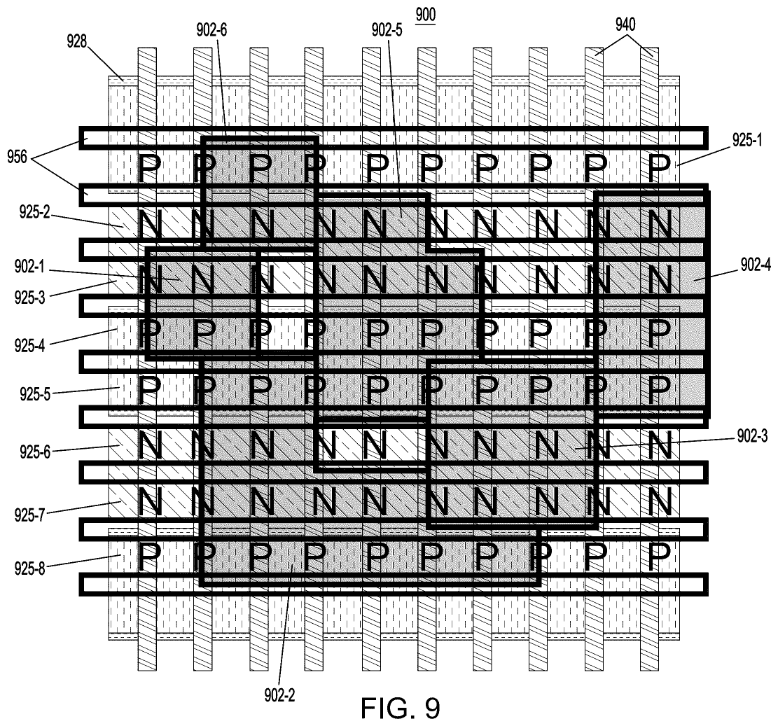

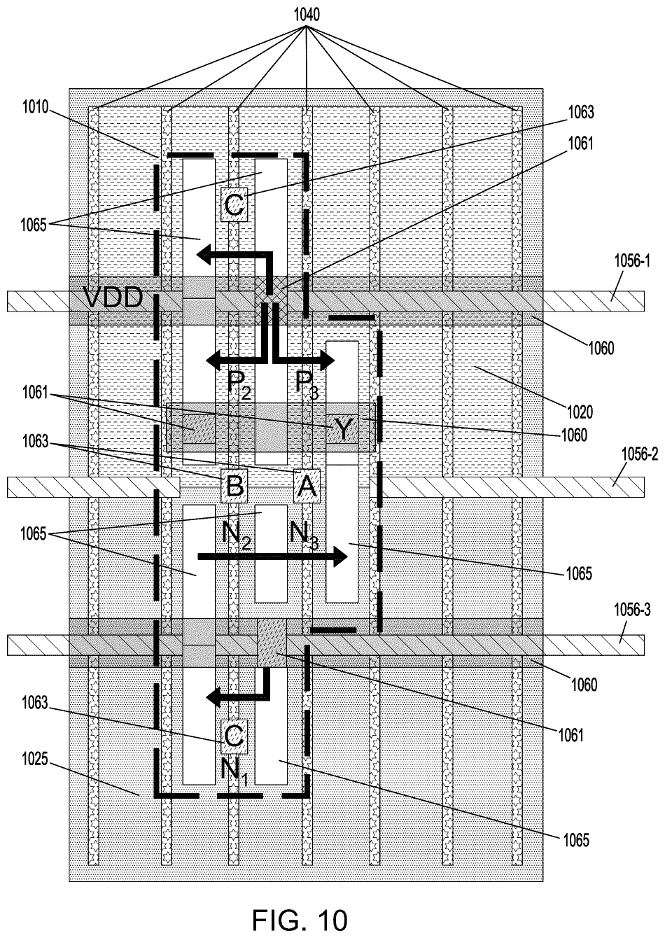

In the embodiment shown in FIG. 7, frontside gate contacts 244 are formed through the ILD layer 238 to land on and contact corresponding portions of the gate structures 240, as shown in FIG. 7. According to an embodiment, masks are formed on parts of the ILD layer 238, and exposed portions of the ILD layer 238 corresponding to where the openings are to be formed are removed using, for example, a dry etching process using a RIE or ion beam etch (IBE) process, a wet chemical etch process or a combination of these etching processes. A dry etch may be performed using a plasma. Such wet or dry etch processes include, for example, IBE by Ar/CHF3 based chemistry. The frontside gate contacts 244 may include a silicide layer such as titanium (Ti), nickel (Ni), nickel platinum (NiPt), etc., and a metal adhesion layer (e.g., such as TiN) and a low resistance metal such as ruthenium (Ru), tungsten (W), cobalt (Co), or another suitable material. It is to be appreciated that the combination of the gate cut regions 256 and the frontside gate contacts 244 enables a set of discrete gate structures 240, thereby offering increased flexibility for complex and efficient gate topologies as discussed in more detail in conjunction with FIGS. 9 and 10, for example.

It is noted that the replacement of the gate cut region with the conductive material 260 is optional, and in alternative embodiments, the gate cut regions 256 can remain intact and frontside gate contacts 244 can be formed on each of the gate structures 240, for example.

The frontside BEOL interconnects 246 are formed on the ILD layer 238 and include various BEOL interconnect structures. The carrier wafer 248 may be formed of materials similar to those used in the semiconductor substrates 201, 203 and may be formed over the frontside BEOL interconnects 246 using a wafer bonding process, such as dielectric-to-dielectric bonding.

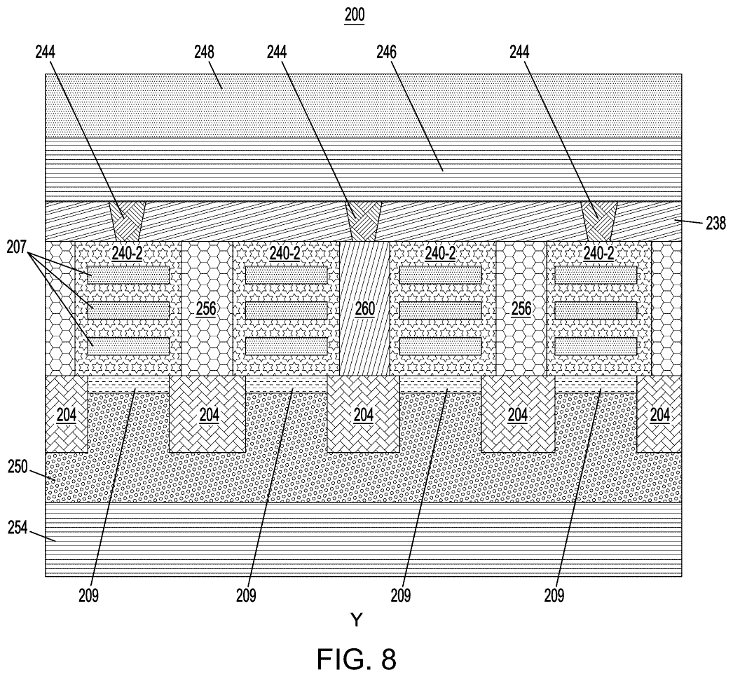

FIG. 8 depicts a cross-sectional view of the semiconductor structure 200 corresponding to line Y in FIG. 2 following removal of the first semiconductor substrate 201, the second semiconductor substrate 203, and the etch stop layer 202, and formation of a backside ILD layer 250 and backside interconnects 254, according to an illustrative embodiment. Using the carrier wafer 248, the structure may be “flipped” and the first semiconductor substrate 201, the etch stop layer 202, and the second semiconductor substrate 203 can be removed.

Following removal of the second semiconductor substrate 203, portions of the bottom surface of the gate structures 240 are exposed, and a backside ILD layer 250 may be formed. The backside ILD layer 250 can include similar materials as the ILD layer 238, for example. In some embodiments, the material of the backside ILD layer 250 may initially be overfilled, followed by a planarization process (e.g., using CMP). In some embodiments, backside bottom source/drain contacts (not shown) can be formed (e.g., through the backside ILD layer 250) to connect one or more source/drain regions to the backside interconnects 254. The backside interconnects 254 are formed on the backside ILD layer 250. The backside interconnects 254 in some embodiments can include various backside power delivery network (BSPDN) structures such as, but not necessarily limited to, interconnects in a power supply path from voltage regulator modules (VRMs) to circuits. The interconnects can comprise, for example, power and ground planes in circuit boards, cables, connectors and capacitors associated with a power supply. Backside power delivery prevents BEOL routing congestion, resulting in power performance benefits. Backside wire resources may also be used for signal wiring and/or clock signal wiring, as needed.

FIG. 9 depicts a top view of a semiconductor structure 900 comprising multiple logic gates 902-1, . . . 902-6 (collectively logic gates 902) according to an illustrative embodiment. The semiconductor structure 900 comprises pFETs (each labeled with P) associated with source/drain regions 925-1, 925-4, 921-5, 925-8 and nFETs (each labeled with N) associated with source/drain regions 925-2, 925-3, 925-6, and 926-7. The semiconductor structure also includes an N-well region 928, where the pFETs are patterned on. The pFETs and nFETs comprise discrete gate structures 940, which can be formed based at least in part on a set of gate cuts 956, as discussed in conjunction with FIGS. 2-8. In this example, the set of gate cuts 956 can be formed using a large-scale regular pattern that results in a grid of the pFETs and the nFETs. In some embodiments, the pattern of gate cuts can be formed by reusing a mask (e.g., a mask used during a self-aligned double patterning (SADP) process). The pFETs and nFETs, in some embodiments, can be left as discrete FETs. This can provide Electronic Design Automation (EDA) tools with new functionality for assembling raw devices into logic gates. For example, FIG. 9 shows standard groupings of vertically adjacent pFETs and nFETs that are formed into structures that more efficiently use the devices relative to conventional circuit row structures. These standard groupings can be used for efficient and complex logic gate patterns. For example, some embodiments described herein enable one or more of the following logic gate reservations:
Non-rectangular pFET reservations per cell (e.g., logic gate 902-5, which can correspond to an NOR3 logic gate);
N-well (NW)/substrate spanning stack assignment for “tall and skinny” logic gates (e.g., logic gate 902-4, which can correspond to an INV2 logic gate);
Logic gates having uneven combinations of pFETs and nFETs for beta optimization (e.g., logic gate 902-3, which can correspond to a NAND2 logic gate having two pFETs and four nFETS); and
Logic gates having complex distributions of pFETs and nFETs for improved transistor density (e.g., logic gate 902-2, which can correspond to an AOI22INVNOR logic gate).

FIG. 10 depicts a top view of a portion of a semiconductor structure 1000 comprising a 3-input NAND (NAND3) logic gate having a non-rectangular shape 1010. In this embodiment, the semiconductor structure 1000 includes an N-well region 1020, a substrate region 1025, a set of gate structures 1040, a set of transistors including three nFETs (N1, N2, N3) and three pFETs (P1, P2, P3), The semiconductor structure 1000 also includes a set of diffusion contacts 1065 and gate contacts 1063, which in some embodiments are to be connected to one or more other metallization layers by a routing tool, for example. The structure 1000 also includes a first metallization layer 1060 (also referred to as an MI layer) associated with vias 1061 that provides connections to the diffusion contacts 1065 of the semiconductor structure 1000.

The labels A, B, and C corresponding to the gate contacts 1063 represent inputs of the NAND3 logic gate, and label Y represents an output of the NAND3 logic gate is labeled. The first metallization layer 1060 includes a source input supply rail (Vdd) and a source input ground rail (Vss). A pattern of gate cut regions 1056-1, 1056-2, 1056-3 (collectively gate cut regions 1056) is formed across the set of gate structures 1040. It is assumed that the gate cut regions 1056 are formed in a similar manner as described above for gate cut regions 256, except that some of the gate structures 1040 have been left intact (e.g., corresponding to the inputs A and B, which are connected to both the FET above and below where the cut would otherwise be). The pattern of gate cut regions 1056 can be formed based on one or more masks (e.g., used during a SADP process). The arrows in FIG. 10 represent the direction charge flows.

Semiconductor devices and methods for forming the same in accordance with the above-described techniques can be employed in various applications, hardware, and/or electronic systems. Suitable hardware and systems for implementing embodiments of the invention may include, but are not limited to, personal computers, communication networks, electronic commerce systems, portable communications devices (e.g., cell and smart phones), solid-state media storage devices, functional circuitry, etc. Systems and hardware incorporating the semiconductor devices are contemplated embodiments of the invention. Given the teachings provided herein, one of ordinary skill in the art will be able to contemplate other implementations and applications of embodiments of the invention.

In some embodiments, the above-described techniques are used in connection with semiconductor devices that may require or otherwise utilize, for example, CMOSs, MOSFETs, and/or FinFETs. By way of non-limiting example, the semiconductor devices can include, but are not limited to CMOS, MOSFET, and FinFET devices, and/or semiconductor devices that use CMOS, MOSFET, and/or FinFET technology.

Various structures described above may be implemented in integrated circuits. The resulting integrated circuit chips can be distributed by the fabricator in raw wafer form (that is, as a single wafer that has multiple unpackaged chips), as a bare die, or in a packaged form. In the latter case the chip is mounted in a single chip package (such as a plastic carrier, with leads that are affixed to a motherboard or other higher-level carrier) or in a multichip package (such as a ceramic carrier that has either or both surface interconnections or buried interconnections). In any case the chip is then integrated with other chips, discrete circuit elements, and/or other signal processing devices as part of either: (a) an intermediate product, such as a motherboard, or (b) an end product. The end product can be any product that includes integrated circuit chips, ranging from toys and other low-end applications to advanced computer products having a display, a keyboard or other input device, and a central processor.

According to one embodiment, a semiconductor device includes a set of transistor devices comprising respective discrete gate structures, a set of gate separation regions, where each discrete gate structure is disposed between a pair of the gate separation regions, and a set of gate contacts, where each gate contact is connected to a corresponding one of the discrete gate structures.

The semiconductor device of the illustrative embodiment advantageously includes a set of gate separation regions, which allows for the creation of discrete gate structures that can be combined or kept separate as needed. The discrete gate structures provide increased flexibility for creating more complex and efficient gate topologies, which can increase device utilization density relative to conventional techniques.

In embodiments, the set of transistor devices may be laid out in a grid pattern.

In embodiments, the semiconductor device may include at least one logic gate corresponding to at least a subset of the transistor devices, where the subset of the transistor devices is located within a non-rectangular shape region within the grid pattern.

In embodiments, the set of transistor devices includes a first p-type transistor device adjacent to a second p-type transistor device, with the first p-type transistor device and the second p-type transistor device separated by one of the gate separation regions.

In embodiments, the set of transistor devices is disposed across a plurality of rows, where at least one of the rows includes at least one of the p-type transistor devices and at least one n-type transistor device.

In embodiments, the semiconductor device includes at least one of a frontside power network and a backside power network.

In embodiments, the semiconductor device includes a non-Manhattan power network comprising one or more frontside power routes for delivering power to at least a portion of the set of transistor devices.

In embodiments, the semiconductor device includes a set of connections, associated with the set of transistor devices, comprising at least one of: (i) one or more opportunistically routed source connections; and (ii) one or more local groupings of source connections.

According to another embodiment, a semiconductor device includes a grid of transistor devices, where the grid transistor devices are laid out in a plurality of rows within the grid, at least one first gate separation region comprising a conductive material, where the first gate separation region is disposed between at least one pair of the transistor devices in the grid, and a plurality of second gate separation regions comprising dielectric material, where the second gate separation regions separate each of the other pairs of the transistor devices in the grid.

The semiconductor device of the illustrative embodiment advantageously includes a grid of transistor devices and gate separation regions that can provide increased flexibility for creating more complex and efficient gate topologies. This can, for example, increase device utilization density relative to conventional techniques.

In embodiments, each of the transistor devices may include a discrete gate structure.

In embodiments, the semiconductor device may include a first gate contact shared by the discrete gate structures corresponding to the at least one pair of the transistor devices.

In embodiments, the semiconductor device may include a set of second gate contacts, where each second gate contact is connected to a respective one of the discrete gate structures corresponding to the other pairs of the transistor devices. The set of transistor devices may include one or more p-type transistor devices and one or more n-type transistor devices.

In embodiments, at least one of the rows within the grid may include at least one of the p-type transistor devices and at least one of the n-type transistor devices.

In embodiments, the semiconductor device may include at least one logic gate corresponding to at least a subset of the transistor devices, where the subset of the transistor devices is located within a non-rectangular shape region within the grid.

According to yet another embodiment, a method includes forming one or more gate structures, removing portions of the one or more gate structures based on a pattern of gate cuts, where the pattern of gate cuts separates each transistor device in a set of transistor devices, and depositing a dielectric material into the removed portions of the one or more gate structures, to form a plurality of discrete gate regions.

The method of the illustrative embodiment advantageously includes a pattern of gate cuts separating each transistor device, which can enable, for example, a self-aligned patterning process to be used instead of a conventional mask process. The method of the illustrative embodiment can also further improve the uniformity of the resulting gate cut regions and improve patterning constraints (e.g., minimum cut width and/or spacing between gate cut and diffusion contact). Additionally, the plurality of discrete gate regions enables more complex and efficient gate topologies and increased device utilization density relative to conventional techniques.

In embodiments, the method further includes replacing the dielectric material corresponding to at least one of the gate cuts between two or more transistor devices in the set of transistor devices with a conductive material.

In embodiments, the method further includes forming at least one gate contact that is shared by the two or more transistor devices in the set.

In embodiments, the at least one gate contact may be formed on the gate conductive material.

In embodiments, the method further includes forming one or more logic gates based on a place and route process of an electronic design automation tool, where the plurality of discrete gate regions enables the place and route process to form non-rectangular reservations of transistor devices in the set of transistor devices.

It should be understood that the various layers, structures, and regions shown in the figures are schematic illustrations that are not drawn to scale. In addition, for ease of explanation, one or more layers, structures, and regions of a type commonly used to form semiconductor devices or structures may not be explicitly shown in a given figure. This does not imply that any layers, structures, and regions not explicitly shown are omitted from the actual semiconductor structures. Furthermore, it is to be understood that the embodiments discussed herein are not limited to the particular materials, features, and processing steps shown and described herein. In particular, with respect to semiconductor processing steps, it is to be emphasized that the descriptions provided herein are not intended to encompass all of the processing steps that may be required to form a functional semiconductor integrated circuit device. Rather, certain processing steps that are commonly used in forming semiconductor devices, such as, for example, wet cleaning and annealing steps, are purposefully not described herein for economy of description.

Moreover, the same or similar reference numbers are used throughout the figures to denote the same or similar features, elements, or structures, and thus, a detailed explanation of the same or similar features, elements, or structures are not repeated for each of the figures. It is to be understood that the terms “approximately” or “substantially” as used herein with regard to thicknesses, widths, percentages, ranges, temperatures, times, and other process parameters, etc., are meant to denote being close or approximate to, but not exactly. For example, the term “approximately” or “substantially” as used herein implies that a small margin of error is present, such as ±5%, preferably less than 2% or 1% or less than the stated amount.

In the description above, various materials, dimensions and processing parameters for different elements are provided. Unless otherwise noted, such materials are given by way of example only and embodiments are not limited solely to the specific examples given. Similarly, unless otherwise noted, all dimensions and process parameters are given by way of example and embodiments are not limited solely to the specific dimensions or ranges given.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A semiconductor device comprising:
a set of transistor devices comprising respective discrete gate structures;
a set of gate separation regions, wherein each discrete gate structure is disposed between a pair of the gate separation regions; and
a set of gate contacts, wherein each gate contact is connected to a corresponding one of the discrete gate structures.

2. The semiconductor device of claim 1, wherein the set of transistor devices is laid out in a grid pattern.

3. The semiconductor device of claim 2, further comprising:
at least one logic gate corresponding to at least a subset of the transistor devices, wherein the subset of the transistor devices is located within a non-rectangular shape region within the grid pattern.

4. The semiconductor device of claim 1, wherein the set of transistor devices comprises a first p-type transistor device adjacent to a second p-type transistor device, with the first p-type transistor device and the second p-type transistor device separated by one of the gate separation regions.

5. The semiconductor device of claim 4, wherein the set of transistor devices are disposed across a plurality of rows, wherein at least one of the rows comprises at least one of the p-type transistor devices and at least one n-type transistor device.

6. The semiconductor device of claim 1, further comprising at least one of:
a frontside power network; and
a backside power network.

7. The semiconductor device of claim 1, further comprising:
a non-Manhattan power network comprising one or more frontside power routes for delivering power to at least a portion of the set of transistor devices.

8. The semiconductor device of claim 1, further comprising:
a set of connections, associated with the set of transistor devices, comprising at least one of: (i) one or more opportunistically routed source connections; and (ii) one or more local groupings of source connections.

9. A semiconductor device comprising:
a grid of transistor devices, wherein the grid of transistor devices is laid out in a plurality of rows within the grid;
at least one first gate separation region comprising a conductive material, wherein the first gate separation region is disposed between at least one pair of the transistor devices in the grid; and
a plurality of second gate separation regions comprising dielectric material, wherein the second gate separation regions separate each of the other pairs of the transistor devices in the grid.

10. The semiconductor device of claim 9, wherein each of the transistor devices comprises a discrete gate structure.

11. The semiconductor device of claim 10, further comprising:
a first gate contact shared by the discrete gate structures corresponding to the at least one pair of the transistor devices.

12. The semiconductor device of claim 11, further comprising:
a set of second gate contacts, wherein each second gate contact is connected to a respective one of the discrete gate structures corresponding to the other pairs of the transistor devices.

13. The semiconductor device of claim 9, wherein the grid of transistor devices comprises one or more p-type transistor devices and one or more n-type transistor devices.

14. The semiconductor device of claim 13, wherein at least one of the rows within the grid comprises at least one of the p-type transistor devices and at least one of the n-type transistor devices.

15. The semiconductor device of claim 9, further comprising:
at least one logic gate corresponding to at least a subset of the transistor devices, wherein the subset of the transistor devices is located within a non-rectangular shape region within the grid.

16. A method comprising:
forming one or more gate structures;
removing portions of the one or more gate structures based on a pattern of gate cuts, wherein the pattern of gate cuts separates each transistor device in a set of transistor devices; and
depositing a dielectric material into the removed portions of the one or more gate structures, to form a plurality of discrete gate regions.

17. The method of claim 16, further comprising:
replacing the dielectric material corresponding to at least one of the gate cuts between two or more transistor devices in the set of transistor devices with a conductive material.

18. The method of claim 17, further comprising:
forming at least one gate contact that is shared by the two or more transistor devices in the set.

19. The method of claim 18, wherein the at least one gate contact is formed on the conductive material.

20. The method of claim 16, further comprising:
forming one or more logic gates based on a place and route process of an electronic design automation tool, wherein the plurality of discrete gate regions enables the place and route process to form non-rectangular reservations of transistor devices in the set of transistor devices.
